(19) United States
(12) Patent Application Publication
(10) Pub. No.: US 2025/0372552 A1
(43) Pub. Date: Dec. 4, 2025

(54) BONDED STRUCTURE WITH HALF-OVAL BONDING PAD PAIR DESIGN AND METHOD OF FORMING THE SAME

(71) Applicant: Taiwan Semiconductor Manufacturing Company, Ltd., Hsinchu (TW)

(72) Inventors: Chan-Wei YEH, Hsinchu City (TW); Wei-Ming WANG, Taichung City (TW); Geng-Ming CHANG, Taichung City (TW); Kewei ZUO, New Taipei City (TW); Ren-Fen TSUI, Taipei (TW)

(21) Appl. No.: 18/731,821

(22) Filed: Jun. 3, 2024

(51) Int. Cl. H01L 23/00; H01L 25/065

(52) U.S. Cl. CPC H01L 24/06; H01L 24/05; H01L 24/08; H01L 24/09; H01L 24/80; H01L 25/0657; H01L 2224/05546; H01L 2224/05555; H01L 2224/06051; H01L 2224/08145; H01L 2224/09055; H01L 2224/80895; H01L 2224/80896

(57) ABSTRACT

A bonded structure and the method of forming the same are provided. The bonded structure includes a first wafer and a second wafer. The first wafer has a first bonding surface and a plurality of first bonding pads exposed from the first bonding surface. The second wafer has a second bonding surface and a plurality of second bonding pads exposed from the second bonding surface. The first bonding surface faces and contacts the second bonding surface, and the first bonding pads are in contact with and electrically connected to the second bonding pads. Each first bonding pad has a circular shape, and each second bonding pad has an oval shape.

### BACKGROUND

The semiconductor industry has continuously grown due to continuous improvements in integration density of a variety of electronic components (e.g., transistors, diodes, resistors, capacitors, etc.). For the most part, these improvements in integration density have come from successive reductions in minimum feature size, which allows more components to be integrated into a given area.

Higher density of electronic components may also be achieved by fabricating three-dimensional (3D) integrated circuit (IC) device structures. Some 3DIC device structures, such as Wafer-on-Wafer (WoW) structures, include stacking and bonding multiple IC devices (i.e., chips) on the semiconductor wafer level. Such 3D bonded wafer device structures may provide improved integration density and other advantages, such as faster speeds and higher bandwidth, because of the decreased length of interconnects between the stacked chips. However, there are many challenges related to 3D devices.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a vertical cross-sectional view of a portion of a first wafer including a plurality of devices, an interconnect structure, and a passivation layer formed on a substrate, in accordance with some embodiments.

FIG. 1B is a vertical cross-sectional view of a portion of a second wafer including a plurality of devices, an interconnect structure, and a passivation layer formed on a substrate, in accordance with some embodiments.

FIG. 2A is a vertical cross-sectional view of a portion of a first wafer including a dielectric layer deposited over the passivation layer and a patterned mask formed over the dielectric layer, in accordance with some embodiments.

FIG. 2B is a vertical cross-sectional view of a portion of a second wafer including a dielectric layer deposited over the passivation layer and a patterned mask formed over the dielectric layer, in accordance with some embodiments.

FIG. 3A is a vertical cross-sectional view of a portion of a first wafer including a plurality of via openings formed through the dielectric layer and a patterned mask formed over the dielectric layer, in accordance with some embodiments.

FIG. 3B is a vertical cross-sectional view of a portion of a second wafer including a plurality of via openings formed through the dielectric layer and a patterned mask formed over the dielectric layer, in accordance with some embodiments.

FIG. 4A is a vertical cross-sectional view of a portion of a first wafer including a plurality of trench openings formed in the dielectric layer, in accordance with some embodiments.

FIG. 4B is a vertical cross-sectional view of a portion of a second wafer including a plurality of trench openings formed in the dielectric layer, in accordance with some embodiments.

FIG. 5A is a vertical cross-sectional view of a portion of a first wafer including a metal material layer deposited over the dielectric layer and filling the trench openings and via openings in the dielectric layer, in accordance with some embodiments.

FIG. 5B is a vertical cross-sectional view of a portion of a second wafer including a metal material layer deposited over the dielectric layer and filling the trench openings and via openings in the dielectric layer, in accordance with some embodiments.

FIG. 6A is a vertical cross-sectional view of a portion of a first wafer including a plurality of bonding pads and conductive vias embedded with the dielectric layer, in accordance with some embodiments.

FIG. 6B is a vertical cross-sectional view of a portion of a second wafer including a plurality of bonding pads and conductive vias embedded with the dielectric layer, in accordance with some embodiments.

FIG. 7 is a vertical cross-sectional view of a portion of a bonded wafer structure including a first wafer bonded to a second wafer, in accordance with some embodiments.

FIG. 8 is a plan view showing an arrangement of top and bottom bonding pads of different sizes.

FIG. 9 is a plan view showing an arrangement of a half-oval bonding pad pair design, in accordance with some embodiments.

FIGS. 10A and 10B are diagrams showing the relationship between the bonding pad overlapped area and overlap shift and the relationship between minimum pad-to-pad spacing and overlap shift, respectively, for different bonding pad pair designs, where each top bonding pad is offset by 0 degrees relative to the corresponding bottom bonding pad.

FIGS. 11A and 11B are diagrams showing the relationship between the bonding pad overlapped area and overlap shift and the relationship between minimum pad-to-pad spacing and overlap shift, respectively, for different bonding pad pair designs, where each top bonding pad is offset by 45 degrees relative to the corresponding bottom bonding pad.

FIG. 12 is a schematic view of an arrangement of a half-oval bonding pad pair design, in accordance with some embodiments.

FIG. 13 is a schematic view of an arrangement of a half-oval bonding pad pair design, in accordance with some embodiments.

FIG. 14 is a schematic view of an arrangement of a half-oval bonding pad pair design, in accordance with some embodiments.

FIG. 15 is a schematic view of an arrangement of a half-oval bonding pad pair design, in accordance with some embodiments.

FIG. 16 is a schematic view of an arrangement of a half-oval bonding pad pair design, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The system may be otherwise oriented (rotated 90 degrees or at other orientations) and the spatially relative descriptors used herein may likewise be interpreted accordingly.

Embodiments of the present disclosure relate to a bonded wafer structure (e.g., a WoW structure), and methods of forming the bonded wafer structure, that includes a novel half-oval bonding pad pair design (e.g., the bonding pads on one side/wafer are circular and the bonding pads on the other side/wafer are oval). The use of this half-oval bonding pad pair design can not only increase the WoW overlay margin (i.e., increased overlapped area of the bonding pad pairs when there is a misalignment between corresponding top and bottom bonding pads) to reduce contact resistance of the bonding pad pairs, but it can also improve pad-to-pad spacing to reduce the risk of leakage (compared to cases in which the critical dimension (CD) of the bonding pads on one side are enlarged), especially at ultra-fine pitches such as sub-micron level (i.e., several hundred nanometers (nm)) pitches. Accordingly, the electrical performance and reliability of the bonded wafer structure can be improved.

The Embodiments discussed herein provide examples to enable making or using the subject matter of this disclosure, and a person having ordinary skill in the art will readily understand that modifications can be made while remaining within the contemplated scope of different embodiments. Throughout the various views and illustrative embodiments, like reference numbers are used to designate like elements. Although method embodiments may be discussed as being performed in a particular order, other method embodiments may be performed in any logical order.

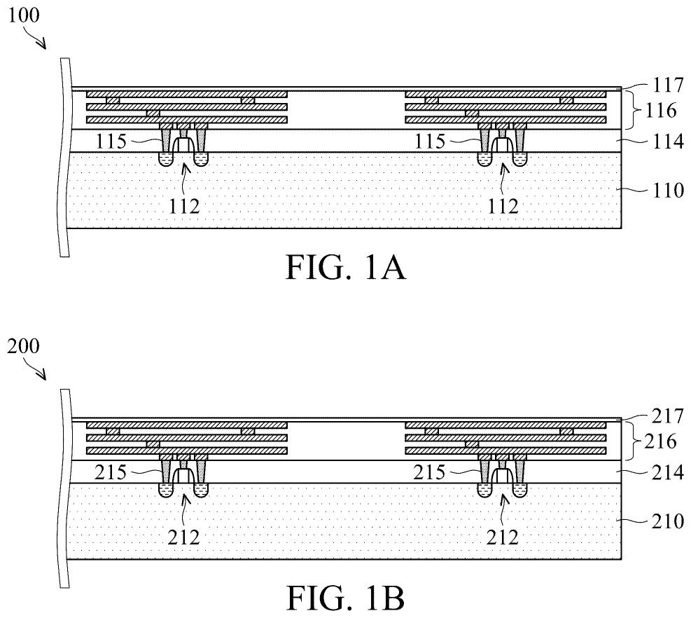

FIGS. 1A to 7 are sequential vertical cross-sectional views of an exemplary structure during a process of forming a bonded wafer structure, such as a WoW structure, according to various embodiments of the present disclosure. The bonded wafer structure may include a plurality of device wafers, each of which may include device structures and an interconnect structure formed on a substrate. The device wafers may be vertically stacked and bonded together to form an integrated bonded wafer device structure. In alternative embodiments (not shown), the bonded wafer structure may include at least one interposer wafer, which contains no active devices and may or may not include passive devices. Although the exemplary embodiment shown in FIGS. 1A to 7 illustrates a process of forming a bonded wafer structure having two wafers, various bonded wafer structures, and methods of forming such structures, that include more than two wafers are also within the contemplated scope of the disclosure.

FIG. 1A is a vertical cross-section view of a portion of a first wafer 100, and FIG. 1B is a vertical cross-section view of a portion of a second wafer 200 in accordance with various embodiments of the present disclosure. Referring to FIGS. 1A and 1B, the first wafer 100 and the second wafer 200 may each include a plurality of device dies (only one device die is shown for simplicity). The illustrated features may be parts of a single device die, which is one among a plurality of identical device dies. The device dies of the wafers 100 and 200 may include logic dies (e.g., central processing unit (CPU) dies, graphics processing unit (GPU) dies, system-on-a-chip (SoC) dies, application processor (AP) dies, microcontroller dies, etc.), memory dies (e.g., dynamic random access memory (DRAM) dies, static random access memory (SRAM) dies, etc.), power management dies (e.g., power management integrated circuit (PMIC) dies), radio frequency (RF) dies, sensor dies, micro-electro-mechanical-system (MEMS) dies, signal processing dies (e.g., digital signal processing (DSP) dies), front-end dies (e.g., analog front-end (AFE) dies), integrated passive devices (IPD), or a combination thereof.

The first wafer 100 and the second wafer 200 may be processed according to applicable manufacturing processes to form integrated circuits in respective device dies. For example, the first wafer 100 and the second wafer 200 may include substrates 110 and 210, respectively. Each of the substrates 110 and 210 may be a semiconductor substrate, such as silicon, doped or undoped, or an active layer of a semiconductor-on-insulator (SOI) substrate. The semiconductor materials of the substrates 110 and 210 may include other semiconductor materials, such as germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or a combination thereof. Other substrates, such as multi-layered or gradient substrates, may also be used.

In alternative embodiments, either the first wafer 100 or the second wafer 200 may be used for forming interposers. In such embodiments, the substrate 110 or 210 may be a dielectric substrate. In other embodiments, one of the substrates 110 or 210 may be a supporting substrate made of quartz, glass, or the like. In various embodiments, the substrate 110 and the substrate 210 may include the same material(s), or may include different materials. Furthermore, through-vias (not shown) may be formed to penetrate the substrate 110 and/or the substrate 210 in order to interconnect components on the opposite sides of the substrate 110 and/or the substrate 210, in some cases.

Referring again to FIGS. 1A and 1B, devices 112 and 212 (represented by transistors) may be formed at the front surfaces (e.g., the surfaces facing upwards in FIGS. 1A and 1B) of the semiconductor substrates 110 and 210, respectively. The devices 112 and 212 may be, e.g., transistors, diodes, capacitors, resistors, or the like. Details of the devices 112 and 212 are not discussed herein. In various embodiments, the devices 112 within the first wafer 100 and the devices 212 within the second wafer 200 may be the same or different devices. In alternative embodiments in which one of the wafers 100 or 200 may be used for forming interposers, the devices 112 or 212 may not be present.

Inter-layer dielectric (ILD) layers 114 and 214 may be formed over the front surfaces of the semiconductor substrates 110 and 210, respectively, and may surround and cover the devices 112 and 212, respectively. The ILD layers 114 and 214 may each include one or more dielectric layers formed of materials such as Phospho-Silicate Glass (PSG), Boro-Silicate Glass (BSG), Boron-Doped Phospho-Silicate Glass (BPSG), undoped Silicate Glass (USG), or the like. Contact plugs 115 and 215 may be formed in the ILD layers 114 and 214, respectively, to electrically and physically couple the devices 112 and 212, respectively. For example, when the devices 112 and 212 are transistors, the contact plugs 115 and 215 may respectively couple the gates and source/drain regions of the transistors to other circuit components. The contact plugs 115 and 215 may be formed of tungsten, cobalt, nickel, copper, silver, gold, aluminum, or a combination thereof.

Interconnect structures 116 and 216 may be formed over the ILD layers 114 and 214 and the contact plugs 115 and 215, respectively. The interconnect structure 116 interconnects the devices 112 to form an integrated circuit, and the interconnect structure 216 interconnects the devices 212 to form an integrated circuit. Each of the interconnect structure 116 and 216 may be formed by, for example, metallization patterns in dielectric layers (sometimes also referred to as inter-metal dielectric (IMD) layers). In accordance with some embodiments, some of IMD layers are formed of low-k dielectric materials having dielectric constant values (k-values) lower than about 3.5 or 3.0. The IMD layers may be formed of or comprise a carbon-containing low-k dielectric material, Hydrogen SilsesQuioxane (HSQ), MethylSilsesQuioxane (MSQ), or the like. The metallization patterns include metal lines and vias formed in one or more low-k dielectric layers by a damascene process, such as a single damascene process, a dual damascene process, or the like. The metallization patterns may be formed of a suitable conductive material, such as copper, tungsten, aluminum, silver, gold, a combination thereof, or the like. The metallization patterns of the interconnect structures 116 and 216 are electrically coupled to the devices 112 and 212 by the contact plugs 115 and 215, respectively.

In some embodiments, the first wafer 100 and the second wafer 200 may also include passivation layers 117 and 217 respectively over their respective topmost lower-k dielectric layers. For example, there may be USG layers, silicon oxide layers, silicon nitride layers, etc., deposited over the low-k dielectric layers. The passivation layers 117 and 217 are denser than the low-k dielectric layers, and have the function of isolating the low-k dielectric layers from detrimental chemicals and gases such as moisture in external environment.

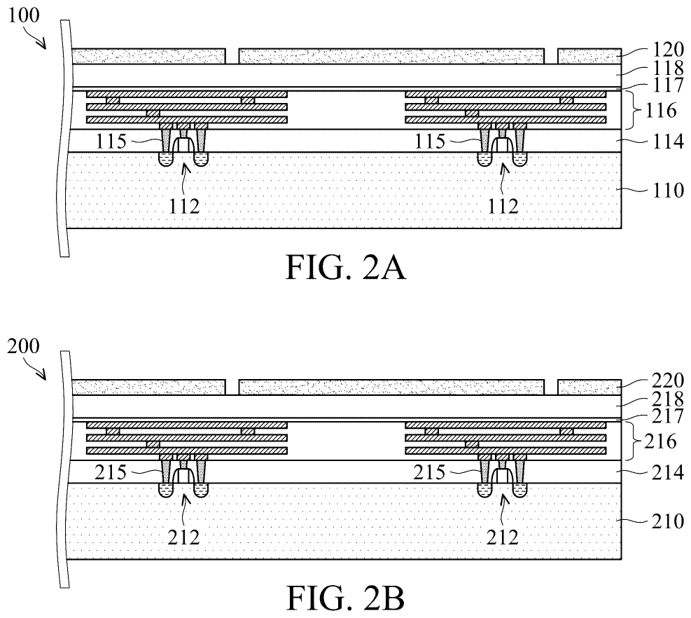

FIGS. 2A to 6B are sequential vertical cross-sectional views illustrating a process of forming bonding layers (BL) over each of the first and second wafers 100 and 200. Referring now to FIGS. 2A and 2B, dielectric layers 118 and 218 may be deposited over the upper surface of respective passivation layers 117 and 217 on each of the first and second wafers 100 and 200. Each of the dielectric layers 118 and 218 may be formed of a polymer such as polybenzoxazole (PBO), polyimide, a benzocyclobutene (BCB) based polymer, or the like; a nitride such as silicon nitride or the like; an oxide such as silicon oxide, PSG, BSG, BPSG, a tetraethyl orthosilicate (TEOS) based oxide; the like, or a combination thereof. The dielectric layers 118 and 218 may be formed by a deposition process such as chemical vapor deposition (CVD), spin coating, lamination, or the like.

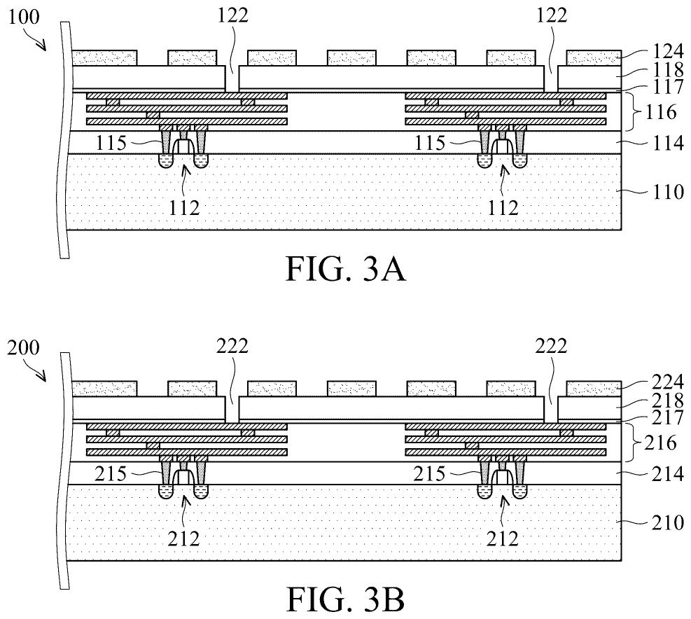

Referring again to FIGS. 2A and 2B, patterned masks 120 and 220 may be formed over the upper surface of respective dielectric layers 118 and 218 on each of the first and second wafers 100 and 200. Each of the patterned masks 120 and 220 may be lithographically patterned to form openings (not specifically marked) through the masks 120 and 220. The openings may correspond to a pattern of via openings that may be subsequently formed through respective dielectric layers 118 and 218 (see FIGS. 3A and 3B). In various embodiments, the patterned mask 120 formed over the dielectric layer 118 on the first wafer 100 may have an identical pattern of openings as the pattern of openings through the patterned mask 220 formed over dielectric layer 218 on the second wafer 200, or may have a different pattern of openings than the patterned mask 220 formed over dielectric layer 218 on the second wafer 200.

FIG. 3A is a vertical cross-section view of a portion of the first wafer 100 showing via openings formed in the dielectric layer 118, and FIG. 3B is a vertical cross-section view of a portion of the second wafer 200 showing via openings formed in the dielectric layer 218. Referring to FIGS. 3A and 3B, an anisotropic etch process may be performed through each of the patterned masks 120 and 220 (see FIGS. 2A and 2B) to remove portions of the dielectric layers 118 and 218 and form via openings 122 and 222 through the dielectric layers 118 and 218. The via openings 122 and 222 may further extend through respective passivation layers 117 and 217 on each of the first and second wafers 100 and 200 to expose the underlying topmost metallization pattern of respective interconnect structures 116 and 216. The patterned masks 120 and 220 may then be removed via a suitable process, such as by ashing or dissolution by a solvent.

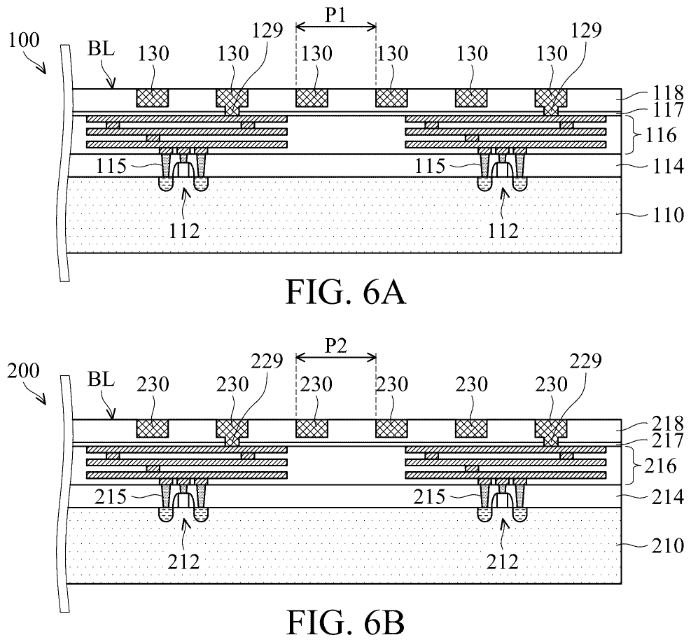

Referring to FIGS. 3A and 3B, additional patterned masks 124 and 224 may be formed over the upper surface of respective dielectric layers 118 and 218 on each of the first and second wafers 100 and 200. Each of the patterned masks 124 and 224 may be lithographically patterned to form openings (not specifically marked) through the masks 124 and 224. The openings may correspond to a pattern of trench openings that may be subsequently formed within respective dielectric material layers 118 and 218. The trench openings may correspond to the locations of metal features that may be subsequently formed in the top bonding layer (BL) of each of the first and second wafers 100 and 200. As discussed in further detail below, the top bonding layer (BL) of each of the first and second wafers 100 and 200 may include an array of bonding pads (see FIGS. 6A and 6B). In various embodiments, the patterned mask 124 formed over the dielectric layer 118 on the first wafer 100 may have an identical pattern of openings as the pattern of openings through the patterned mask 224 formed over dielectric layer 218 on the second wafer 200, or may have a different pattern of openings than the patterned mask 224 formed over dielectric layer 218 on the second wafer 200.

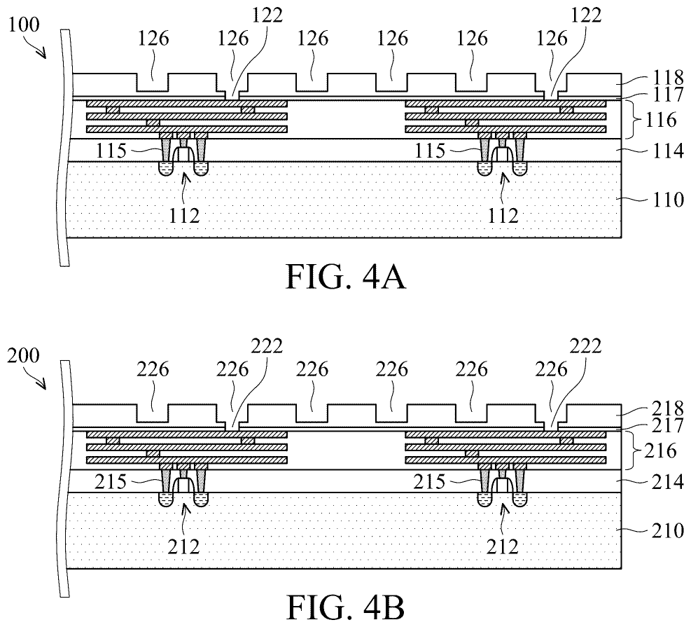

FIG. 4A is a vertical cross-section view of a portion of the first wafer 100 showing a plurality of trench openings 126 formed in the dielectric layer 118, and FIG. 4B is a vertical cross-section view of a portion of the second wafer 200 showing a plurality of trench openings 226 formed in the dielectric layer 218. Referring to FIGS. 4A and 4B, an anisotropic etch process may be performed through each of the patterned masks 124 and 224 (see FIGS. 3A and 3B) to remove portions of the dielectric layers 118 and 218 and form trench openings 126 and 226 within the dielectric layers 118 and 218. In some embodiments, in the cross-section shown, some of the trench openings 126 and 226 are disposed above and connected to respective via openings 122 and 222 while other trench openings 126 and 226 are not disposed above or connected to any via openings 122 and 222. The patterned masks 124 and 224 may then be removed via a suitable process, such as by ashing or dissolution by a solvent.

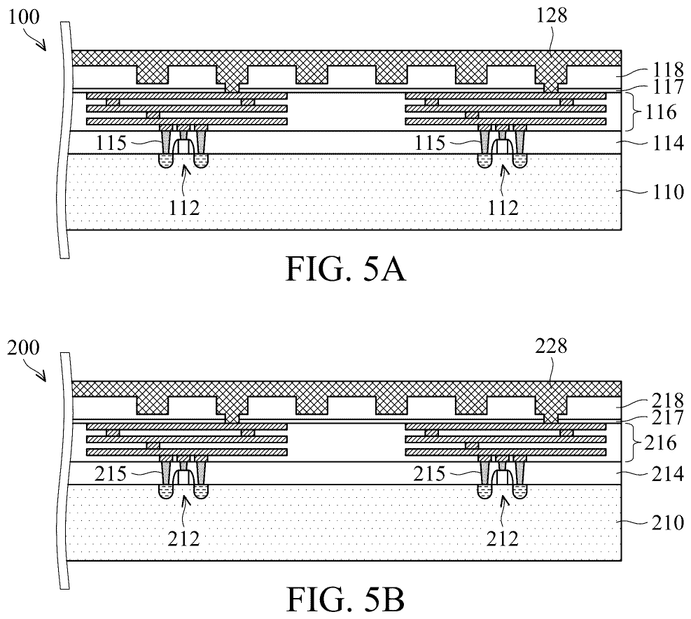

FIG. 5A is a vertical cross-sectional view of a portion of the first wafer 100 including a metal material layer 128 deposited over the upper surface of the dielectric layer 118 and filling the trench openings 126 and via openings 122 (see FIG. 4A) in the dielectric layer 118, and FIG. 5B is a vertical cross-sectional view of a portion of the second wafer 200 including a metal material layer 228 deposited over the upper surface of the dielectric layer 218 and filling the trench openings 226 and via openings 222 (see FIG. 4B) in the dielectric layer 218. Referring to FIGS. 5A and 5B, the metal material layers 128 and 228 may be formed of a suitable metal material, such as tungsten (W), copper (Cu), a copper alloy, aluminum (Al), an aluminum alloy, or a combination thereof. Other suitable electrically conductive materials are within the contemplated scope of disclosure. In some embodiments, thin barrier layers (not shown) composed of a suitable barrier material, such as Ta, TaN, Ti, TiN, CoW, or a combination thereof, may be first deposited over the upper surfaces of the dielectric layers 118, 218 and within the trench openings 126, 226 and via openings 122, 222, and the metal material layers 128 and 228 may be then deposited over barrier layers. The metal material layers 128 and 228 and the barrier layers, if present, may be deposited using a suitable deposition process, which may include one or more of a CVD process, a physical vapor deposition (PVD) process, an atomic layer deposition (ALD) process, an electroplating process, or the like.

FIG. 6A is a vertical cross-sectional view of a portion of the first wafer 100 including a plurality of bonding pads 130 and conductive vias 129 embedded with the dielectric layer 118, and FIG. 6B is a vertical cross-sectional view of a portion of the second wafer 200 including a plurality of bonding pads 230 and conductive vias 229 embedded with the dielectric layer 218. Referring to FIGS. 6A and 6B, each of the first and second wafers 100 and 200 may undergo a planarization process, such as a chemical mechanical planarization (CMP) process, to remove the metal material layers 128 and 228 (see FIGS. 5A and 5B) and the barrier layers, if present, from above the upper surfaces of the dielectric layers 118 and 218. The remaining portion of the metal material layers 128, 228 located within the trench openings 126, 226 and via openings 122, 222 may form bonding pads 130, 230 and conductive vias 129, 229 embedded with respective dielectric layers 118, 218. Each of the bonding pads 130, 230 may have an exposed upper surface and may be laterally surrounded by respective dielectric layers 118, 218. The exposed bonding pads 130, 230 and the corresponding dielectric layers 118, 218 form a bonding layer (BL) on each of the first and second wafers 100 and 200. Some of the bonding pads 130, 230 may be connected to the topmost metallization pattern within respective interconnect structures 116, 216 through the conductive vias 129, 229.

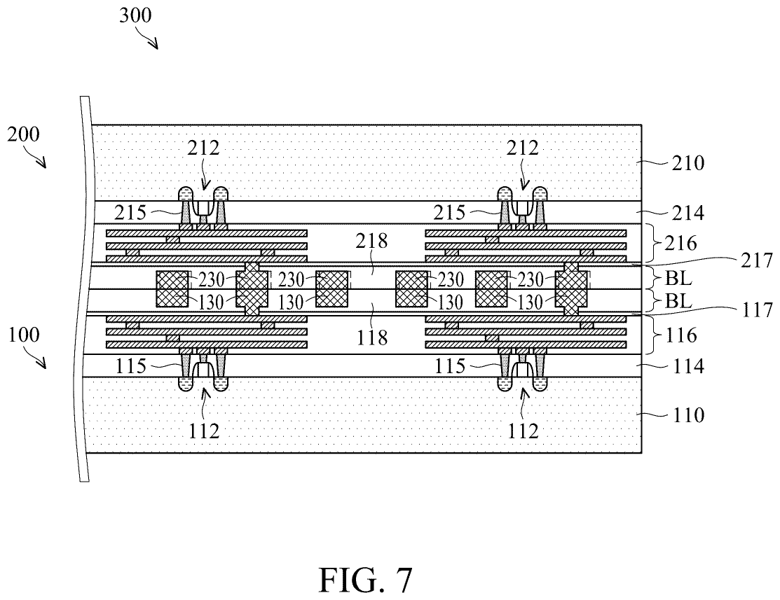

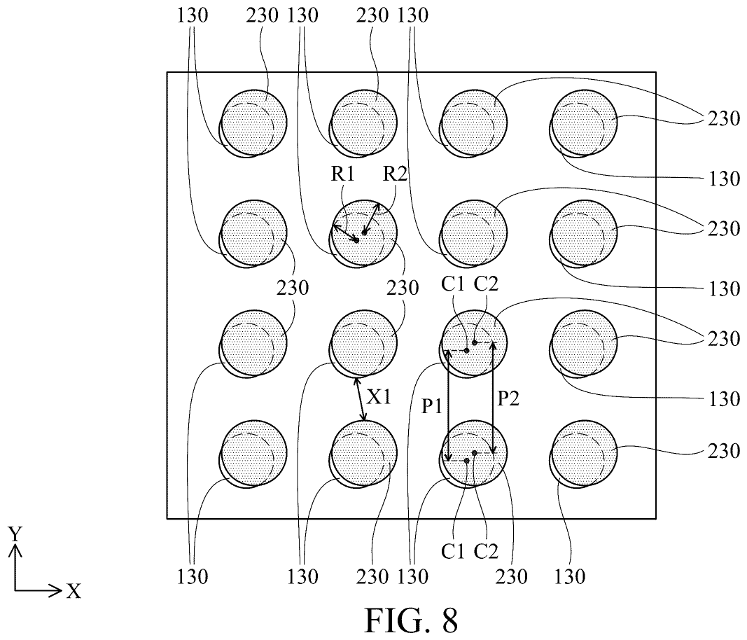

In accordance with some embodiments, the bonding pads 130 of the first wafer 100 may be arranged in a rectangular array in plan view (e.g., see FIG. 8) with a consistent first pitch P1, and the bonding pads 230 of the second wafer 200 may also be arranged in a rectangular array in plan view (e.g., see FIG. 8) with a consistent second pitch P2, wherein the first pitch P1 is equal to the second pitch P2, so that the bonding pads 130 of the first wafer 100 may be aligned with and contact the corresponding bonding pads 230 of the second wafer 200 during a subsequent bonding process (see FIG. 7). In various embodiments, the minimum diameter of each bonding pad 130, 230 may be half the corresponding pad-to-pad pitch P1, P2.

FIG. 7 is a vertical cross-sectional view of a portion of a bonded wafer structure 300 including the first wafer 100 bonded to the second wafer 200, in accordance with some embodiments. Referring to FIG. 7, the first wafer 100 is bonded to the second wafer 200 using a hybrid bonding technique. For example, covalent bonds may be formed between oxide layers, such as the dielectric layers 118 and 218 of the bonding layers (BL) of the first and second wafers 100 and 200. During the hybrid bonding, direct metal-to-metal bonding also occurs between the bonding pads 130 and 230 within the bonding layers (BL) of the first and second wafers 100 and 200, thereby electrical connection is formed between the first and second wafers 100 and 200.

In some embodiments, before performing the bonding process, the surfaces of the bonding layers (BL) of the first and second wafers 100 and 200 may optionally be pre-treated to promote surface activation (e.g., using a plasma treatment process). The second wafer 200 may then be flipped (e.g., inverted) and stacked onto the first wafer 100 using, for example, a pick-and-place tool, so that the bonding layer (BL) of the second wafer 200 faces the bonding layer (BL) of the first wafer 100 (the first wafer 100 and the second wafer 200 may also be referred to herein as the bottom wafer 100 and the top wafer 200). The first wafer 100 and the second wafer 200 may also be aligned such that the (bottom) bonding pads 130 of the first/bottom wafer 100 contact the corresponding (top) bonding pads 230 of the second/top wafer 200. The stacks of wafers 100 and 200 may then be subjected to a thermal treatment and/or pressed against each other (e.g., by applying contact pressure) to bond the wafers 100 and 200. The bonding process may result in diffusion bond forming between the bonding pads 130 of the first wafer 100 and the corresponding bonding pads 230 of the second wafer 200. Consequently, the bonded wafer structure 300 is formed. In various embodiments, the bonded wafer structure 300 may then be singulated (e.g., diced, not shown) to provide a plurality of integrated circuit (IC) chips.

It should be noted that for various reasons, misalignment between the wafers 100 and 200 may occur in the bonding process, such that the (top) bonding pads 230 of the second/top wafer 200 may not align accurately with the corresponding (bottom) bonding pads 130 of the first/bottom wafer 100 (FIG. 7 also shows offset top bonding pads 230 in dashed lines). In some cases, the misalignment between corresponding bonding pads 130 and 230 (and thus a reduction in the contact or overlapped area of the bonding pad pairs) can cause increased contact resistance or open connections, which in turn results in reduced electrical performance and reliability of the resulting bonded structure (e.g., the bonded wafer structure 300). This problem is more severe when adjacent pads have ultra-fine pitches, such as sub-micron level pitches.

In order to enlarge WoW overlay margin (i.e., increase the contact or overlapped area of the bonding pad pairs when there is a misalignment between corresponding top and bottom bonding pads), an approach of enlarging the critical dimension (e.g., radius) of the bonding pads on one side (i.e., unequal sized bonding pad pairs) has been proposed. As an example, FIG. 8 schematically illustrates a plan view of the arrangement of top and bottom bonding pads of different sizes. In the example of FIG. 8, the first pitch P1 of the bottom bonding pads 130 on the first/bottom wafer 100 is equal to the second pitch P2 of the top bonding pads 230 on the second/top wafer 200 (i.e., P1=P2, e.g., about 200 nm), and the radius R2 (e.g., about 60 nm) of the top bonding pads 230 of the second/top wafer 200 is greater than the radius R1 (e.g., about 50 nm) of the bottom bonding pads 130 of the first/bottom wafer 100. Other pitches and other radii of the bonding pads 130 and 230 are also possible, and/or the sizes of the bonding pads 130 and 230 may be interchanged.

Although the approach utilizing unequal sized bonding pad pairs can improve WoW overlay margin (i.e., increase overlapped area) when there is a misalignment between corresponding top and bottom bonding pads 130 and 230 (for example, the centers C1 of the bonding pads 130 are offset from the centers C2 of the bonding pads 230, as shown in FIG. 8), larger critical dimension (and therefore larger size) results in smaller pad-to-pad spacing. For example, due to the increased critical dimension (e.g., radius) of the bonding pads (e.g., 230) on one side, the (minimum) pad-to-pad spacing X1 (see FIG. 8) between adjacent top and bottom bonding pads 130 and 230 is reduced compared with cases in which the top and bottom bonding pads 130 and 230 are the same size. This reduced pad-to-pad spacing X1 results in increased risks of leakage between adjacent top and bottom bonding pads 130 and 230, especially at ultra-fine pitches, thereby reducing the reliability of the bonded structure. Therefore, a solution is needed to overcome the above problems (i.e., increase WoW overlay margin without affecting pad-to-pad spacing margin).

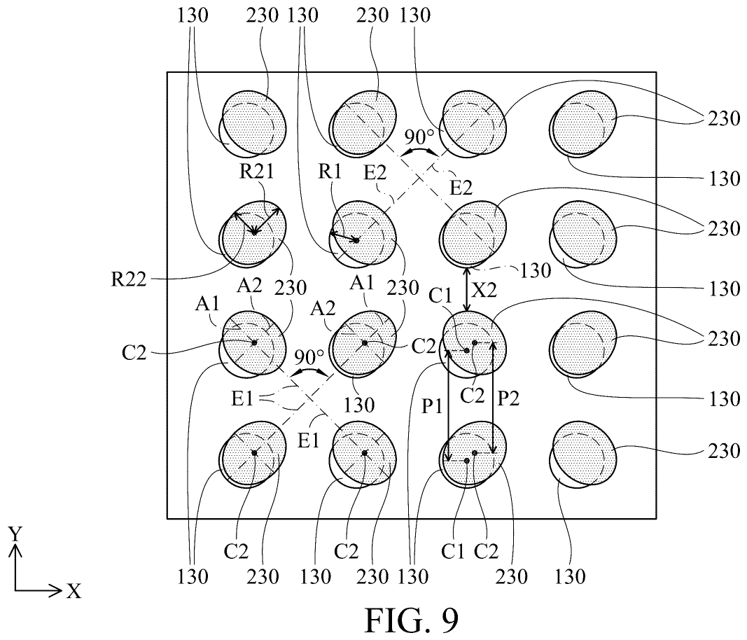

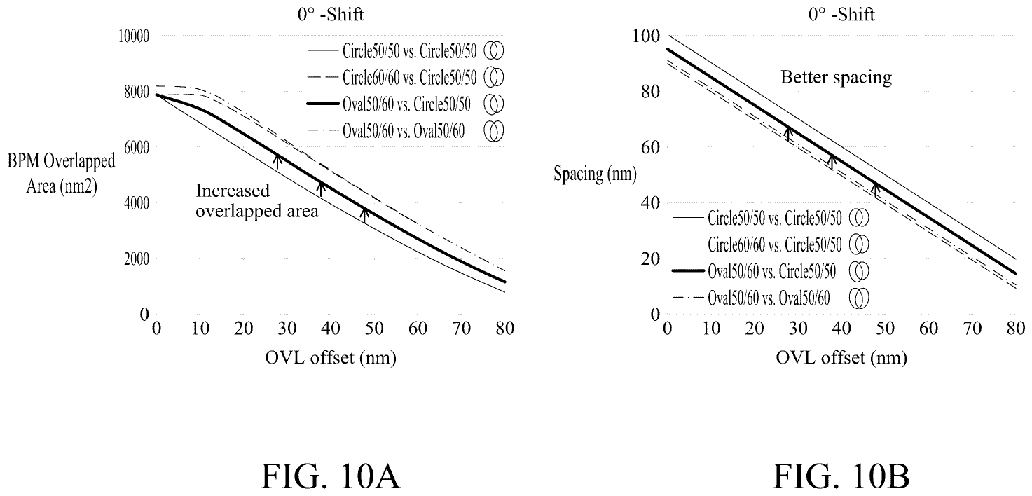

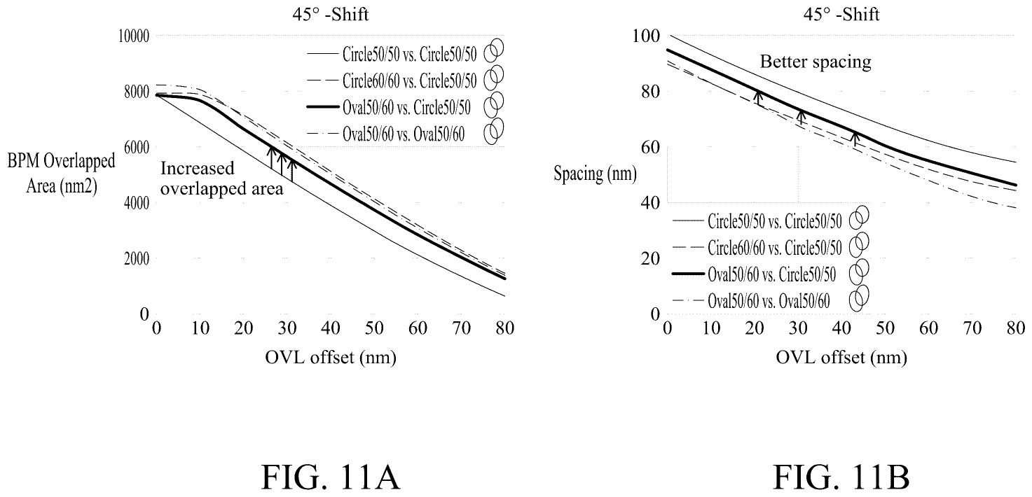

FIG. 9 schematically illustrates a plan view of the arrangement of a novel half-oval bonding pad pair design that can solve the above problems, in accordance with some embodiments. The term “half-oval bonding pad pair” as used herein represents that the bonding pads on one side/wafer are circular and the bonding pads on the other side/wafer are oval. Referring to FIG. 9, the arrangement of the top and bottom bonding pads 130 and 230 may be similar to that shown in FIG. 8, but the bonding pads on one side (e.g., the top bonding pads 230) are changed to an oval shape. In alternative embodiments, the bottom bonding pads 130 may be changed to an oval shape while the top bonding pads 230 remains circular. It has been found that the half-oval bonding pad pair design provides better improvements in pad-to-pad spacing margin than all-oval bonding pad pair design (i.e., the bonding pads on both sides/wafers are oval), which will be further described below with reference to FIGS. 10A to 11B.

In the example of FIG. 9, the oval bonding pads 230 may be arranged in such a manner that the major axis A1 of each oval bonding pad 230 forms an included angle of 45 degrees or 135 degrees with the X-direction. Furthermore, the virtual parallel extension lines E1 of the major axes A1 of two adjacent oval bonding pads 230 arranged along the X-direction intersect at 90 degrees, and the virtual parallel extension lines E1 of the major axes A1 of two adjacent oval bonding pads 230 arranged along the Y-direction intersect at 90 degrees, so that the virtual parallel extension lines E1 of the major axes A1 of each 2×2 array of oval bonding pads 230 intersect to form a cross (and the virtual parallel extension lines E2 of the minor axes A2 of each 2×2 array of oval bonding pads 230 also intersect to form a cross). In this manner, each 2×2 array of oval bonding pads 230 form a petal-shaped pattern. Other included angles of the major axis of each oval bonding pad relative to the X-direction may be used.

Since each oval bonding pads 230 with extended major axis A1 has an increased size, the WoW overlay margin for the same bonding pad pair can be increased. Furthermore, since the major axis A1 of each oval bonding pad 230 forms an included angle of 45 degrees or 135 degrees with the X-direction, and each 2×2 array of oval bonding pads 230 form a petal-shaped pattern, the pad-to-pad spacing margin can also be improved (e.g., the (minimum) pad-to-pad spacing X2 between adjacent top and bottom bonding pads 130 and 230 is increased compared to cases in which the critical dimension of the bonding pads on one side is enlarged, i.e., X2>X1) regardless of the offset of the top and bottom bonding pads 130 and 230 in any direction (e.g., offset by 45 degrees, as shown in FIG. 9), which will be further described below with reference to FIGS. 10A to 11B.

In accordance with some embodiments, the semi-minor axis length R22 of each oval bonding pad 230 is equal to the radius R1 of the corresponding circular bonding pad 130 in the same bonding pad pair, while in other embodiments the semi-minor axis length R22 of each oval bonding pad 230 may be larger or smaller than the radius R1 of the corresponding circular bonding pad 130 in the same bonding pad pair. In accordance with some embodiments, for each oval bonding pad 230, the ratio of the semi-major axis length R21 (or the major axis length) to the semi-minor axis size R22 (or the minor axis size) needs to be less than 2:1. If the ration is equal to 2:1, the (minimum) pad-to-pad spacing X2 is almost 0 nm, which will result in an increased risk of leakage between adjacent top and bottom bonding pads 130 and 230.

Next, referring to FIGS. 10A to 11B, which illustrate simulation results related to the overlapped area and pad-to-pad spacing for four different bonding pad pair designs (i.e., Design 1: equal sized bonding pad pairs; Design 2: unequal sized bonding pad pairs (e.g., the example of FIG. 8); Design 3: half-oval bonding pad pairs (e.g., the example of FIG. 9); and Design 4: all-oval bonding pad pairs). It should be understood that the oval bonding pads in Designs 3 and 4 are arranged to have a layout (i.e., each 2×2 array of oval bonding pads 230 form a petal-shaped pattern) similar to that shown in FIG. 9. The radius of each circular bonding pad, or the semi-minor axis length and semi-major axis length of each oval bonding pad for various designs are marked in the diagrams of FIGS. 10A to 11B.

FIGS. 10A and 10B are diagrams showing the relationship between the bonding pad overlapped area and overlap shift and the relationship between minimum pad-to-pad spacing and overlap shift, respectively, for different bonding pad pair designs, where each top bonding pad is offset by 0 degrees (i.e., offset in a direction parallel the X-direction) relative to the corresponding bottom bonding pad. FIGS. 11A and 11B are diagrams showing the relationship between the bonding pad overlapped area and overlap shift and the relationship between minimum pad-to-pad spacing and overlap shift, respectively, for different bonding pad pair designs, where each top bonding pad is offset by 45 degrees (i.e., offset in a direction tiled 45 degrees relative to the X-direction, as shown in FIG. 9) relative to the corresponding bottom bonding pad. It should be understood that the simulation results of the overlapped area and pad-to-pad spacing for cases in which each top bonding pad is offset by 90 degrees (i.e., offset in a direction parallel the Y-direction) relative to the corresponding bottom bonding pad are similar to cases in which there is an offset of 0 degrees, so they are not shown separately. As can be seen from these diagrams, in either the case of an offset of 0 degrees or the case of an offset of 45 degrees, for the half-oval bonding pad pair design/structure, the overlapped area is increased, and the pad-to-pad spacing is better (i.e., increased) than other designs including the unequal sized bonding pad pair design/structure and the all-oval bonding pad pair design/structure. In addition, the overlapped area and pad-to-pad spacing of the all-oval bonding pad pair design/structure are comparable to those of the unequal sized bonding pad pair design/structure (that is, the all-oval bonding pad pair design/structure does not improve pad-to-pad spacing margin as does the unequal sized bonding pad pair design/structure).

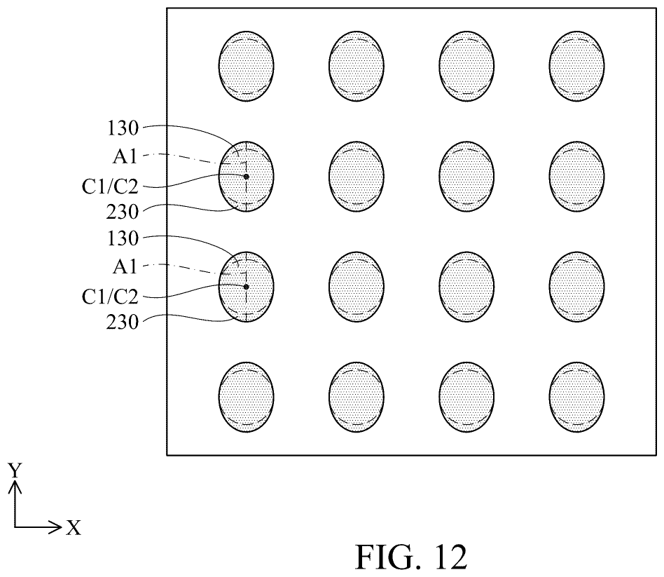

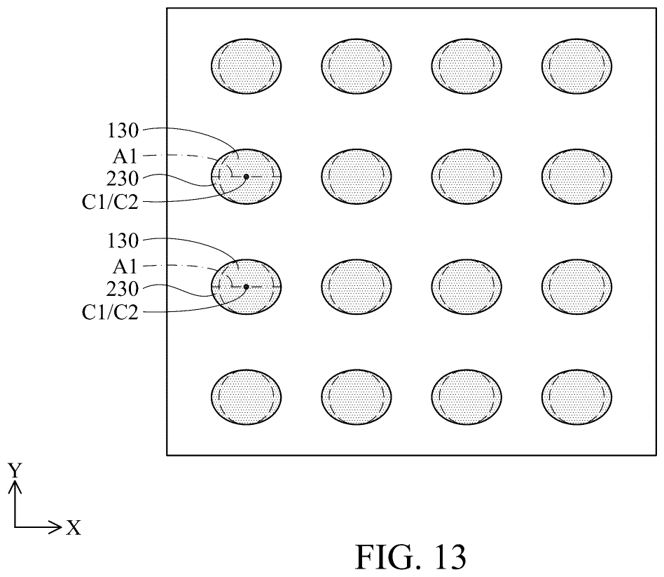

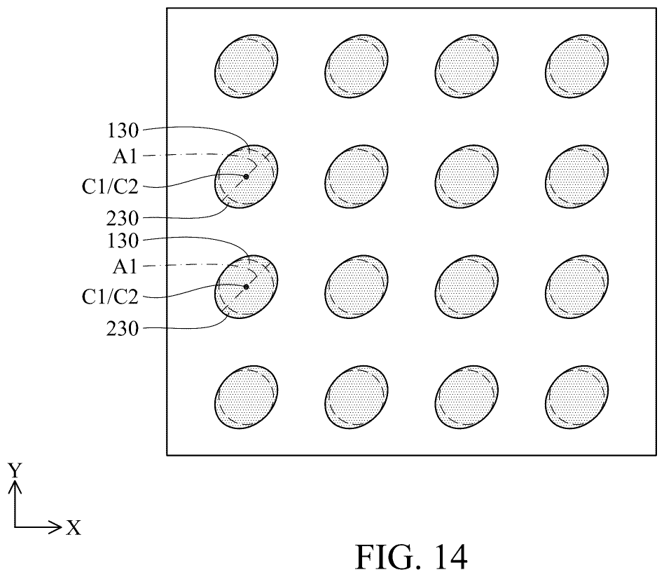

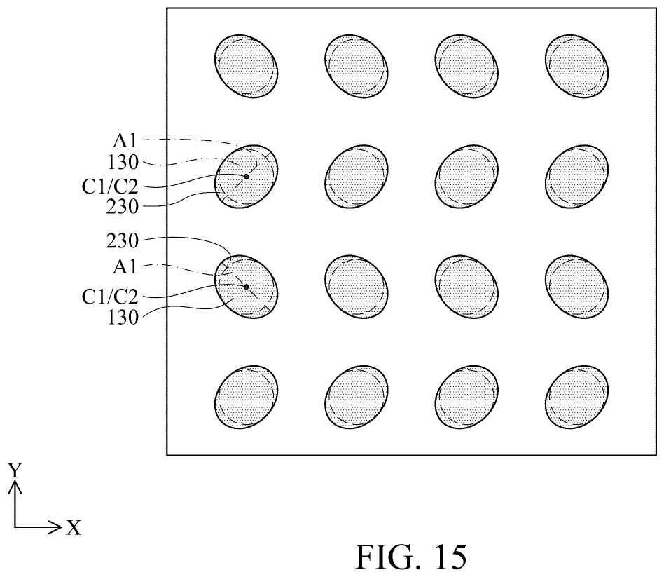

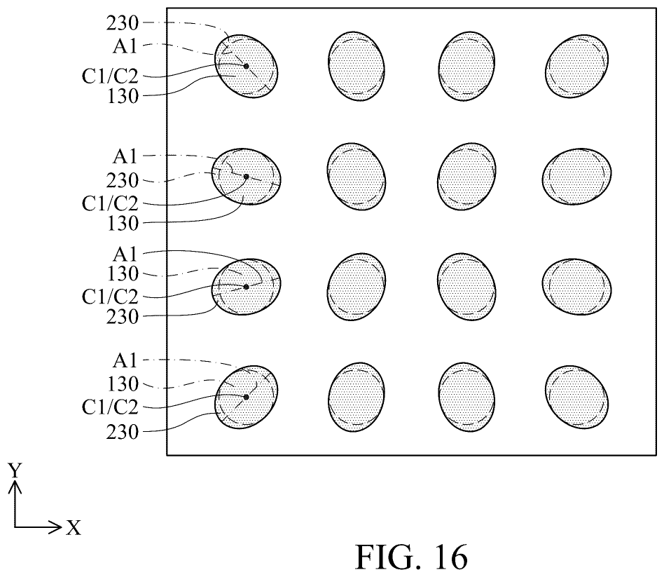

Many variations and/or modifications can be made to embodiments of the disclosure. For example, the oval bonding pads on the same side/wafer (e.g., top bonding pads 230) may have various layout/arrangement variations as shown in FIGS. 12 to 16. In the examples of FIGS. 12 to 14, the oval bonding pads 230 are arranged in such a manner that the major axes A1 of all oval bonding pads 230 are aligned in the same direction, e.g., the Y-direction (FIG. 12), the X-direction (FIG. 13), or the +45-degree diagonal direction (FIG. 14). In other words, the major axis directions of all oval bonding pads 230 are parallel to each other. In the example of FIG. 15, the oval bonding pads 230 may have a plurality of major axis directions that are not parallel to each other. For example, the major axes A1 of some oval bonding pads 230 are aligned along the +45-degree diagonal direction, and the major axes A1 of other oval bonding pads 230 are aligned along the −45-degree diagonal direction. The oval bonding pads 230 in the same row may have the same major axis direction, and the oval bonding pads 230 in adjacent rows may have different (e.g., mutually perpendicular) major axis directions. In the example of FIG. 16, the major axis directions of the oval bonding pads 230 varies in various directions, including the X-direction, the Y-direction, and the +/−45-degree diagonal directions. The above layout can be selected based on the offset directions between the top and bottom bonding pads (for simplicity, not shown in FIGS. 12 to 16). In various embodiments, the centers C1 and C2 of the top and bottom bonding pads 130 and 230 may be aligned with each other, as shown in FIGS. 12 to 16, or may be offset from each other.

It should be understood that the structures, configurations and the manufacturing methods described herein are only illustrative, and are not intended to be, and should not be construed to be, limiting to the present disclosure. Many alternatives and modifications will be apparent to those skilled in the art, once informed by the present disclosure.

In addition, while the present disclosure is described using embodiments in which a half-oval bonding pad pair design is applied to the WoW structure, embodiments are expressly contemplated herein in which the half-oval bonding pad pair design may also be applied to other bonded structures, such chip-on-wafer (CoW), chip-on-chip (CoC) structures, etc. For example, such a bonded structure may include a first package component (e.g., a wafer or chip) and a second package component (e.g., a wafer or chip) bonded together using hybrid bonding, one utilizing oval bonding pads and the other utilizing circular bonding pads.

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

In summary, the embodiments of the present disclosure have some advantageous features. The use of a novel half-oval bonding pad pair design can not only increase the WoW overlay margin, but it can also improve pad-to-pad spacing to reduce the risk of leakage (compared to cases in which the critical dimension of the bonding pads on one side are enlarged), especially at ultra-fine pitches such as sub-micron level pitches. Accordingly, the electrical performance and reliability of the bonded wafer structure can be improved.

In accordance with some embodiments, a bonded structure is provided. The bonded structure includes a first wafer (substrate) and a second wafer (substrate). The first wafer has a first bonding surface and a plurality of first bonding pads exposed from the first bonding surface. The second wafer has a second bonding surface and a plurality of second bonding pads exposed from the second bonding surface. The first bonding surface faces and contacts the second bonding surface, and the first bonding pads are in contact with and electrically connected to the second bonding pads. Each first bonding pad has a circular shape, and each second bonding pad has an oval shape.

In accordance with some embodiments, a bonded structure is provided. The bonded structure includes a first package component and a second package component. The first package component has a first bonding surface and a plurality of first bonding pads exposed from the first bonding surface. The package component has a second bonding surface and a plurality of second bonding pads exposed from the second bonding surface. The first bonding surface faces and contacts the second bonding surface, and the first bonding pads are in contact with and electrically connected to the second bonding pads to form a plurality of bonding pad pairs. In each bonding pad pair, the first bonding pad is circular, and the corresponding second bonding pad is oval shaped.

In accordance with some embodiments, a method of forming a bonded structure is provided. The method includes providing a first wafer having a plurality of first bonding pads, wherein each first bonding pad has a circular shape. The method also includes providing a second wafer having a plurality of second bonding pads, wherein each second bonding pad has an oval shape. The method also includes stacking the first wafer and the second wafer on top of each other such that the first bonding pads are aligned with and contacting the second bonding pads. In addition, the method includes bonding the first wafer to the second wafer through metal-to-metal bonding of the first bonding pads and the second bonding pads.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A bonded structure, comprising:
a first substrate having a first bonding surface and a plurality of first bonding pads exposed from the first bonding surface; and
a second substrate having a second bonding surface and a plurality of second bonding pads exposed from the second bonding surface,
wherein the first bonding surface faces and contacts the second bonding surface, and the plurality of first bonding pads are in contact with and electrically connected to the plurality of second bonding pads, and
wherein each of the plurality of first bonding pads has a circular shape, and each of the plurality of second bonding pads has an oval shape.

2. The bonded structure as claimed in claim 1, wherein the plurality of first bonding pads have a first pitch, and the plurality of second bonding pads have a second pitch equal to the first pitch.

3. The bonded structure as claimed in claim 1, wherein a ratio of a semi-major axis length to a semi-minor axis length of one of the plurality of second bonding pads is less than 2:1.

4. The bonded structure as claimed in claim 3, wherein the semi-minor axis length of one of the plurality of second bonding pads is equal to a radius of the corresponding one of the plurality of first bonding pads.

5. The bonded structure as claimed in claim 1, wherein when viewed from a direction perpendicular to the second bonding surface, some of the plurality of second bonding pads are arranged along a first direction, and some of the plurality of second bonding pads are arranged along a second direction perpendicular to the first direction.

6. The bonded structure as claimed in claim 5, wherein a major axis of each of the plurality of second bonding pads forms an included angle of 45 degrees or 135 degrees with the first direction.

7. The bonded structure as claimed in claim 6, wherein virtual parallel extension lines of the major axes of two adjacent second bonding pads of the plurality of second bonding pads arranged along the first direction intersect at 90 degrees, and virtual parallel extension lines of the major axes of two adjacent second bonding pads of the plurality of second bonding pads arranged along the second direction intersect at 90 degrees.

8. The bonded structure as claimed in claim 5, wherein major axes of all of the second bonding pads are aligned in the same direction that is parallel, perpendicular, or oblique to the first direction.

9. The bonded structure as claimed in claim 1, wherein the second bonding pads have a plurality of major axis directions that are not parallel to each other.

10. The bonded structure as claimed in claim 1, wherein centers of the plurality of first bonding pads are offset from centers of the plurality of second bonding pads in a plan view.

11. A bonded structure, comprising:
a first package component having a first bonding surface and a plurality of first bonding pads exposed from the first bonding surface; and
a second package component having a second bonding surface and a plurality of second bonding pads exposed from the second bonding surface,
wherein the first bonding surface faces and contacts the second bonding surface, and the plurality of first bonding pads are in contact with and electrically connected to the plurality of second bonding pads to form a plurality of bonding pad pairs, and
wherein in each bonding pad pair of the plurality of bonding pad pairs, the first bonding pad is circular, and the corresponding second bonding pad is oval.

12. The bonded structure as claimed in claim 11, wherein when viewed from a direction perpendicular to the second bonding surface, some of the plurality of second bonding pads are arranged along a first direction, and some of the plurality of second bonding pads are arranged along a second direction perpendicular to the first direction.

13. The bonded structure as claimed in claim 12, wherein virtual parallel extension lines of major axes of two adjacent second bonding pads of the plurality of second bonding pads arranged along the first direction intersect at 90 degrees, and virtual parallel extension lines of major axes of two adjacent second bonding pads of the plurality of second bonding pads arranged along the second direction intersect at 90 degrees.

14. The bonded structure as claimed in claim 11, wherein the first package component and the second package component are both wafers.

15. The bonded structure as claimed in claim 14, wherein one of the first package component and the second package component is a device wafer, and the other is an interposer wafer.

16. A method of forming a bonded structure, comprising:
providing a first wafer having a plurality of first bonding pads, wherein each of the plurality of first bonding pads has a circular shape;
providing a second wafer having a plurality of second bonding pads, wherein each of the plurality of second bonding pads has an oval shape;
stacking the first wafer and the second wafer on top of each other such that the plurality of first bonding pads are aligned with and contacting the plurality of second bonding pads; and
bonding the first wafer to the second wafer through metal-to-metal bonding of the plurality of first bonding pads and the plurality of second bonding pads.

17. The method as claimed in claim 16, wherein the first wafer comprises a first bonding layer surrounding the plurality of first bonding pads, and the second wafer comprises a second bonding layer surround the plurality of second bonding pads, and
wherein the bonding further comprises bonding the first wafer to the second wafer through dielectric-to-dielectric bonding of the first bonding layer and the second bonding layer.

18. The method as claimed in claim 16, wherein the plurality of first bonding pads have a first pitch, and the plurality of second bonding pads have a second pitch equal to the first pitch, and
wherein the first pitch and the second pitch are sub-micron level pitches.

19. The method as claimed in claim 16, wherein some of the plurality of second bonding pads are arranged along a first horizontal direction, and some of the plurality of second bonding pads are arranged along a second horizontal direction perpendicular to the first horizontal direction, and
wherein the plurality of second bonding pads are arranged in such a manner that virtual parallel extension lines of major axes of two adjacent second bonding pads of the plurality of second bonding pads arranged along the first horizontal direction intersect at 90 degrees, and virtual parallel extension lines of major axes of two adjacent second bonding pads of the plurality of second bonding pads arranged along the second horizontal direction intersect at 90 degrees.

20. The method as claimed in claim 16, wherein some of the plurality of second bonding pads are arranged along a first horizontal direction, and some of the plurality of second bonding pads are arranged along a second horizontal direction perpendicular to the first horizontal direction, and
wherein the plurality of second bonding pads are arranged in such a manner that major axes of all of the second bonding pads are aligned in the same direction that is parallel, perpendicular, or oblique to the first horizontal direction.
